(19) United States
(12) Patent Application Publication
(10) Pub. No.: US 2024/0222116 A1
(43) Pub. Date: Jul. 4, 2024

(54) METHOD, SYSTEM AND APPARATUS FOR FORMING EPITAXIAL TEMPLATE LAYER

(71) Applicant: ASM IP Holding B.V., Almere (NL)

(72) Inventors: Gregory Deye, Seattle, WA (US); Caleb Miskin, Mesa, AZ (US)

(21) Appl. No.: 18/398,995

(22) Filed: Dec. 28, 2023

Related U.S. Application Data
(60) Provisional application No. 63/478,028, filed on Dec. 30, 2022.

(51) Int. Cl. H01L 21/02; C23C 16/24; C23C 16/455; C23C 16/458; C23C 16/52; C23C 16/56; C30B 25/18

(52) U.S. Cl. CPC H01L 21/0262; C23C 16/24; C23C 16/45544; C23C 16/45553; C23C 16/4583; C23C 16/52; C23C 16/56; C30B 25/186; H01L 21/02576; H01L 21/02579

(57) ABSTRACT

A semiconductor processing system, comprising a chamber configured to support a substrate, a first precursor source, a second precursor source and a dopant source connected to the chamber and a controller operably connected the first precursor source, the second precursor source and the dopant source. The controller responsive to instructions recorded on a memory is to support a substrate within a chamber of a semiconductor processing system, flow a first precursor into the chamber in contact with a first surface of the substrate, form a template layer of silicon-containing film on the first surface of the substrate, etch non-uniformities on the first surface of the substrate, flow a dopant-containing precursor into the chamber in contact with a second surface of the substrate wherein the second surface is a top surface of the template layer, and form a nucleation layer on the second surface.

### CROSS-REFERENCE TO RELATED APPLICATIONS

This application claims priority to and the benefit of U.S. Provisional Patent Application No. 63/478,028, filed Dec. 30, 2022, the contents of which are incorporated herein by reference in their entirety.

### FIELD OF INVENTION

The present disclosure generally relates to surface treatment of silicon wafers. More particularly, the present disclosure relates to providing a surface treatment prior to deposition of a nucleation layer.

### BACKGROUND OF THE DISCLOSURE

A variety of methods are used in the semiconductor manufacturing industry to deposit materials onto surfaces. For example, one of the most widely used of such methods is chemical vapor deposition (“CVD”), in which atoms or molecules contained in a vapor deposit on a surface and build up to form a film.

In some applications, it is desirable to achieve uniform or “blanket” deposition over both insulating (for example, silicon oxide) and semiconductive (for example, silicon) surfaces. In epitaxial substrate processing, epitaxial growth often starts with a nucleation layer which may be a thin layer of material that is grown on a substrate in order to facilitate growth of a single crystal layer of material on a top surface. The nucleation layer serves as a seed for the crystal growth, providing a uniform and ideally defect-free surface upon which the crystal may grow. Deposition of silicon containing materials using conventional silicon sources and deposition methods on certain surfaces, such as insulators, is believed to proceed in several distinct stages. Nucleation, the first stage, occurs as the first few atoms or molecules deposit onto the surface and form nuclei. Nucleation is greatly affected by the nature and quality of the underlying substrate surface. During the second stage, the isolated nuclei form small islands that grow into larger islands. In the third stage, the growing islands begin coalescing into a continuous film.

Conventionally, a nucleation layer is grown or deposited directly on a substrate surface. To prepare the substrate surface for growth of the nucleation layer, native oxides that may have grown on the substrate surface are removed because any oxide will impact the quality of the epitaxial layers since epitaxial growth relies on lattice matching or extension of a crystal lattice. Thus, residual oxides or other non-uniformities will result in defects. There are several methods for removing native oxides from the surface of a substrate in epitaxial silicon growth. One common method is to use a chemical solution, such as hydrofluoric acid (HF), to etch away the native oxide layer. Alternatively, a high-temperature annealing process may be used to remove the native oxide layer. This can be done in a furnace or using a halogen lamp, for example. The high temperatures cause the native oxide to decompose and evaporate. It is also possible to use physical methods, such as mechanical polishing or sputter cleaning, for example, to remove native oxide layers. These methods involve using abrasive materials or high-energy particles to remove the oxide layer from the surface of the substrate. Regardless of the method used, it is important to clean and prepare the substrate surface to ensure good quality epitaxial growth. Typically, however, the above methods leave behind surface preparation artifacts such as residual oxides, notches, raised areas and other non-uniformities on the surface of a substrate.

Such systems and methods for depositing nucleation layers have generally been considered suitable for their intended purpose. However, there remains a need in the art for improved methods of forming a nucleation layer. The present disclosure provides a solution to this need.

### SUMMARY OF THE DISCLOSURE

A material layer deposition method is provided. The method includes supporting a substrate within a chamber of a semiconductor processing system, flowing a first precursor into the chamber to contact a first surface of the substrate, forming a template layer of silicon-containing film on the first surface of the substrate, etching non-uniformities on the first surface of the substrate, flowing a dopant-containing precursor into the chamber to contact a second surface of the substrate wherein the second surface is a top surface of the template layer and forming a nucleation layer on the second surface.

In addition to one or more of the features described above, or as an alternative, further examples may include that the first precursor is a selective silicon precursor and wherein the etching is performed by a decomposition byproduct of the selective silicon precursor. The method may include that the selective silicon precursor is dichlorosilane.

In addition to one or more of the features described above, or as an alternative, further examples may include that flowing the first precursor further comprises exposing the first precursor to the substrate for about 1 to about 50 seconds. The method may include flowing the first precursor further comprises exposing the first precursor to the substrate until the template layer is about 1.0 nm to about 3.0 nm thick.

In addition to one or more of the features described above, or as an alternative, further examples may include that the dopant-containing precursor is an n-type metal-oxide-semiconductor (nMOS) precursor comprising phosphine (PH₃), arsine (AsH₃) or tert-butylarsine (C₄H₉As), or a combination thereof. The method may include that the dopant-containing precursor is co-flowed with a second precursor that is different from the first precursor.

In addition to one or more of the features described above, or as an alternative, further examples may include that the dopant-containing precursor is a p-type metal-oxide-semiconductor (pMOS) precursor comprising diborane (B₂H₆) and wherein the dopant-containing precursor is co-flowed with a second precursor.

In addition to one or more of the features described above, or as an alternative, further examples may include that forming the nucleation layer on the second surface further comprises applying heat or pressure or a combination thereof to diffuse a dopant into the template layer. The method may include that a temperature within the chamber is about 100° to about 800° C. and wherein a pressure within the chamber is about 5 Torr to about 600 Torr.

A semiconductor processing system is provided. The semiconductor processing system includes a chamber configured to support a substrate, a first precursor source, a second precursor source and a dopant source connected to the chamber, and a controller operably connected the first precursor source, the second precursor source and the dopant source, wherein the controller responsive to instructions recorded on a memory to support a substrate within a chamber of a semiconductor processing system flow a first precursor into the chamber to contact with a first surface of the substrate, form a template layer of silicon-containing film on the first surface of the substrate, etch non-uniformities on the first surface of the substrate simultaneously with forming the template layer, flow a dopant-containing precursor into the chamber in contact with a second surface of the substrate wherein the second surface is a top surface of the template layer, and form a nucleation layer on the second surface.

In addition to one or more of the features described above, or as an alternative, further examples may include that the first precursor is a selective silicon precursor, wherein a decomposition byproduct of the selective silicon precursor is an etchant. The semiconductor processing system may further include that the selective silicon precursor is dichlorosilane.

In addition to one or more of the features described above, or as an alternative, further examples may include that flowing the first precursor further comprises exposing the first precursor to the substrate for about 1 to about 50 seconds. The semiconductor processing system may further include that flowing the first precursor further comprises exposing the first precursor to the substrate until the template layer is between about 1 nm to about 3 nm thick.

In addition to one or more of the features described above, or as an alternative, further examples may include that the dopant-containing precursor is an nMOS precursor comprising phosphine (PH₃), arsine (AsH₃) or tert-butylarsine (C₄H₉As), or a combination thereof. The semiconductor processing system may include that the dopant-containing precursor is a pMOS precursor comprising diborane (B₂H₆).

In addition to one or more of the features described above, or as an alternative, further examples may include diffusing a dopant into the template layer. The semiconductor processing system may further include that a temperature is about 100° C. to about 800° C. and wherein a pressure is about 5 Torr to about 600 Torr.

In addition to one or more of the features described above, or as an alternative, further examples may include that the dopant-containing precursor is co-flowed with a second precursor that is different from the first precursor.

A computer program product, is provided. The computer program product includes a non-transitory machine-readable medium having one or more program modules recorded thereon containing instructions that, when read by a processor, causes the processor, responsive to instructions, to execute material layer deposition method provided above.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram illustrating an example a semiconductor processing system;

FIG. 2 is a schematic diagram illustrating an example precursor delivery arrangement and exhaust arrangement;

FIG. 3 is a schematic diagram illustrating an example semiconductor processing chamber arrangement;

FIG. 4 is a schematic diagram illustrating an example method for depositing a material onto a substrate to form a template layer; and

FIGS. 5A-5E are flow charts illustrating an example material deposition method for depositing a template layer onto a substrate.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

As used herein, the term “epitaxial layer” may refer to a substantially single crystalline layer upon an underlying substantially single crystalline layer or substrate.

As used herein, the term “chemical vapor deposition” may refer to any process wherein a substrate is exposed to one or more volatile precursors, which react and/or decompose on a substrate surface to form thereon a desired layer material.

As used herein, the term “silicon-germanium” may refer to a semiconductor material comprising silicon and germanium and may be represented as Si1-xGex.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

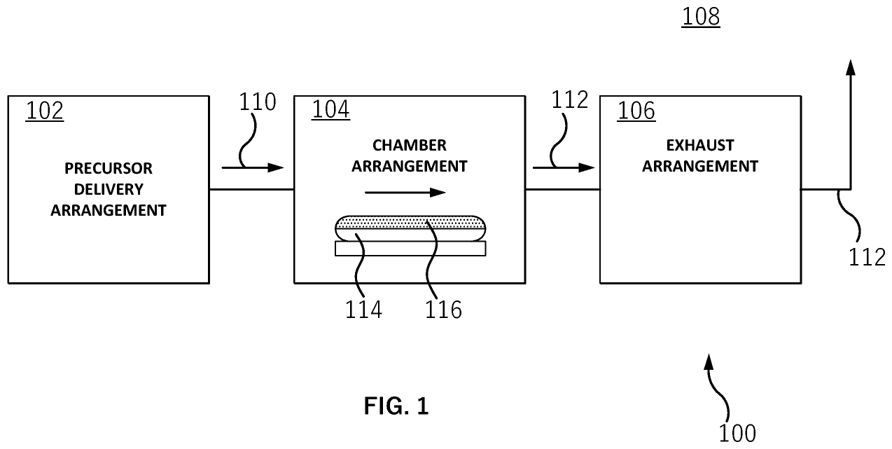

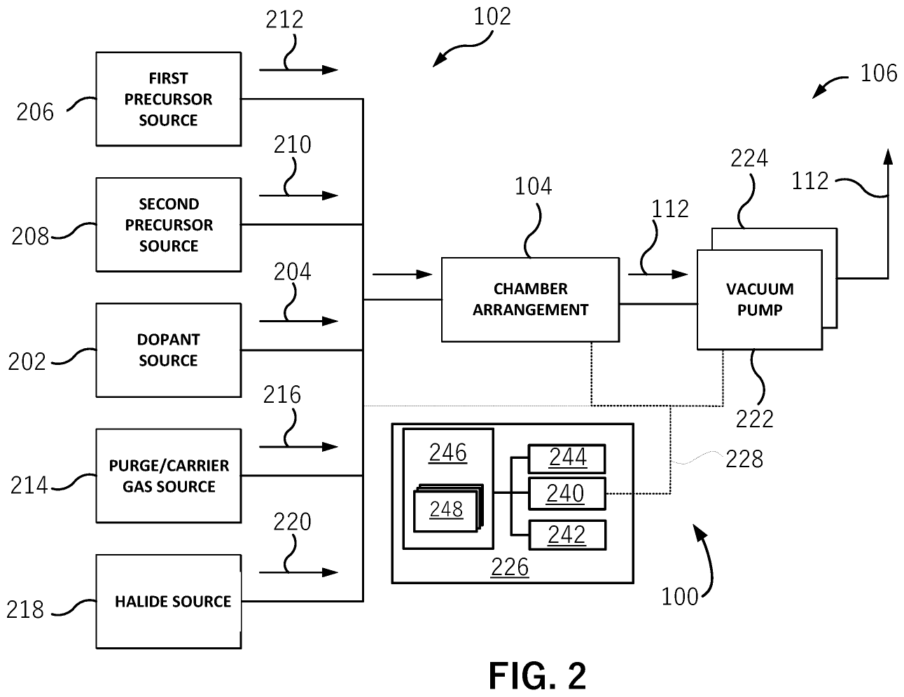

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases. Reference will now be made to the drawings wherein like reference numerals identify similar structural features or aspects of the subject disclosure. For purposes of explanation and illustration, and not limitation, a partial view of an example of a semiconductor processing system 100 in accordance with the present disclosure is shown in FIG. 1 and is designated generally by reference character 100. Other examples of chamber arrangements, semiconductor processing systems, and methods of depositing material layers onto substrates in accordance with the present disclosure, or aspects thereof, are provided in FIGS. 2-5, as will be described. The systems and methods of the present disclosure can be used for deposition of a template layers onto substrates, such as during the deposition of epitaxial material layers onto substrates during the fabrication of semiconductor devices, though the present disclosure is not limited to epitaxial material layers or to the fabrication of any particular type of semiconductor device.

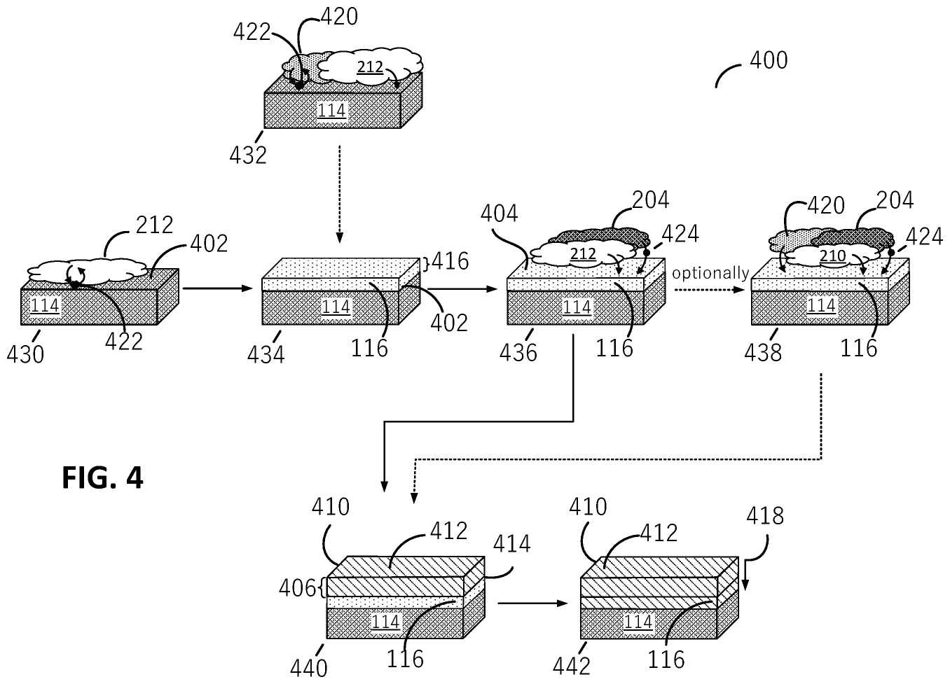

With reference to FIG. 1, a semiconductor processing system 100 is shown. The semiconductor processing system 100 includes a precursor delivery arrangement 102, the chamber arrangement 104, and an exhaust arrangement 106. The precursor delivery arrangement 102 is connected to the chamber arrangement 104 and is configured to provide a precursor 110 to the chamber arrangement 104. The chamber arrangement 104 is connected to the exhaust arrangement 106 and is configured to deposit a template layer 116 and/or nucleation layer 410 (see FIG. 4) onto a substrate 114 supported within the chamber arrangement 104 using the precursor 110. In an example, template layer 116 may comprise a silicon-containing film. The exhaust arrangement 106 is in fluid communication with the environment 108 external to the semiconductor processing system 100 and is configured to communicate a flow of residual precursor and/or reaction products 112 to the environment 108 external to the semiconductor processing system 100. Semiconductor processing system 100 may be configured for processing of substrate 114 such as for epitaxial growth of a template layer 116 and/or nucleation layer 410 (see FIG. 4) onto a substrate surface for NMOS and PMOS fabrication. In an example, semiconductor processing system 100 may be operable for use for a variety of semiconductor processing techniques such as chemical vapor deposition (CVD) or atomic layer deposition (ALD) techniques.

With reference to FIG. 2, the precursor delivery arrangement 102, chamber arrangement and the exhaust arrangement 106 are shown. The precursor delivery arrangement 102 includes a first precursor source 206, a second precursor source 208, and a dopant source 202. The precursor delivery arrangement 102 also includes a purge/carrier gas source 214 and a halide source 218. The first precursor source 206 is connected to the chamber arrangement 104, includes a first precursor 212, and is configured to provide a flow of the first precursor 212 to the chamber arrangement 104. Non-limiting examples of suitable first precursors include dichlorosilane (H₂SiCl₂) and trichlorosilane (HCl₃Si), and non-chlorinated silicon-containing precursors, such as silane (SiH₄), disilane (Si₂H₆), tert-butylarsine (C₄H₉As), monomethyl silane (CH₃SiH₃), and/or trisilane (Si₃H₈).

In an example, the second precursor source 208 is connected to the chamber arrangement 104, may include a second precursor 210, and is configured to provide a flow of the second precursor 210 to the chamber arrangement 104. Non-limiting examples of a suitable second precursor 210 include germane (GeH₄), dichlorosilane (H₂SiCl₂) and trichlorosilane (HCl₃Si), and non-chlorinated silicon-containing precursors, such as silane (SiH₄), disilane (Si₂H₆), tert-butylarsine (C₄H₉As), monomethyl silane (CH₃SiH₃), and/or trisilane (Si₃H₈). The dopant source 202 is similarly connected to the chamber arrangement 104, includes a dopant-containing precursor 204, and is further configured to provide a flow to the dopant-containing precursor 204 to the chamber arrangement 104. In certain examples the dopant-containing precursor 204 may include phosphorous (P), phosphine (PH₃), arsine (AsH₃), diborane (B₂H₆), and/or phosphorus trichloride (PCl₃). It is also contemplated that the dopant-containing precursor 204 may include different or additional species and remain within the scope of the present disclosure.

In an example, the purge/carrier gas source 214 is further connected to the chamber arrangement 104, includes a purge/carrier gas 216, and is additionally configured to provide a flow of the purge/carrier gas 216 to the chamber arrangement 104. In this respect the purge/carrier gas source 214 may be configured to employ the purge/carrier gas 216 to carry one or more of the first precursor 212, the second precursor 210, and/or the dopant-containing precursor 204 into the chamber arrangement 104. Examples of suitable purge/carrier gases include hydrogen (H₂) gas, nitrogen (N₂) gas, inert gases such as argon (Ar) gas or helium (He) gas, and mixtures thereof.

In an example, the halide source 218 is connected to the chamber arrangement 104, includes a halide-containing material 220, and is configured to provide a flow of the halide-containing material 220 to the chamber arrangement 104. The halide-containing material 220 may be co-flowed with the precursors 210 or 212. The halide-containing material 220 may be flowed independently from the precursors 210 or 212, such as to provide a purge and/or to remove condensate from within the chamber arrangement 104. Examples of suitable halides include chlorine (Cl), e.g., chlorine (Cl₂) gas, dichlorosilane (H₂SiCl₂), trichlorosilane (H₂SiCl₂) and hydrochloric (HCl) acid, as well as fluorine (F), e.g., fluorine (F₂) gas and hydrofluoric (HF) acid.

In an example, the exhaust arrangement 106 is configured to evacuate the chamber arrangement 104 and in this respect may include one or more vacuum pump 222 and/or an abatement apparatus 44. The one or more vacuum pump 222 may be connected to the chamber arrangement 104 and configured to control pressure within the chamber arrangement 104. The abatement apparatus 224 may be connected to the one or more vacuum pump 222 and configured to process the flow a residual precursor and/or reaction products 112 issued by the chamber arrangement 104. It is contemplated that the exhaust arrangement 106 may be configured to maintain environmental conditions within the chamber arrangement 104 suitable for atmospheric deposition operations, such as pressures between about 100 Torr and about 800 Torr, such as during high-pressure deposition of epitaxial material layers including Silicon Phosphide (SiP). The exhaust arrangement 106 may also be configured to maintain environmental conditions within the exhaust arrangement 106 suitable for reduced pressure deposition operations, such as pressures between about 0.1 Torr and about 100 Torr, such as during the deposition of epitaxial material layers including using reduced pressure techniques.

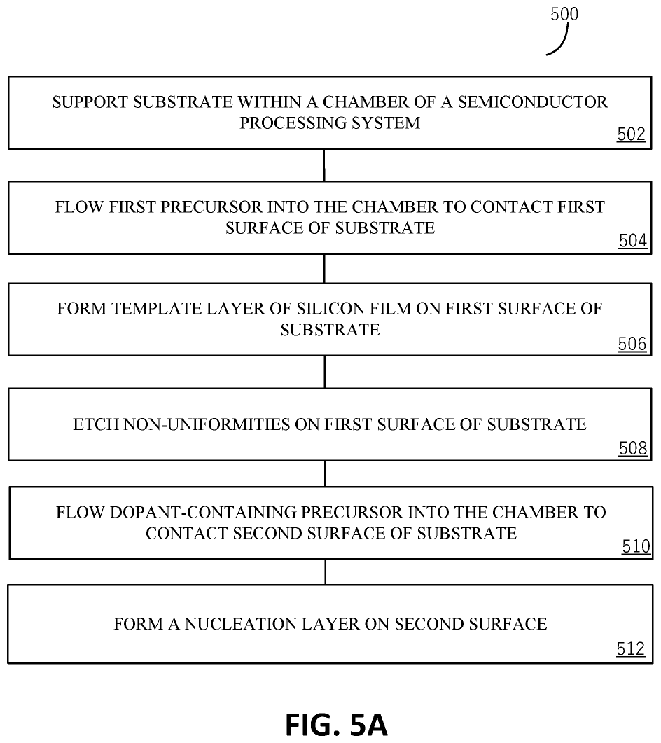

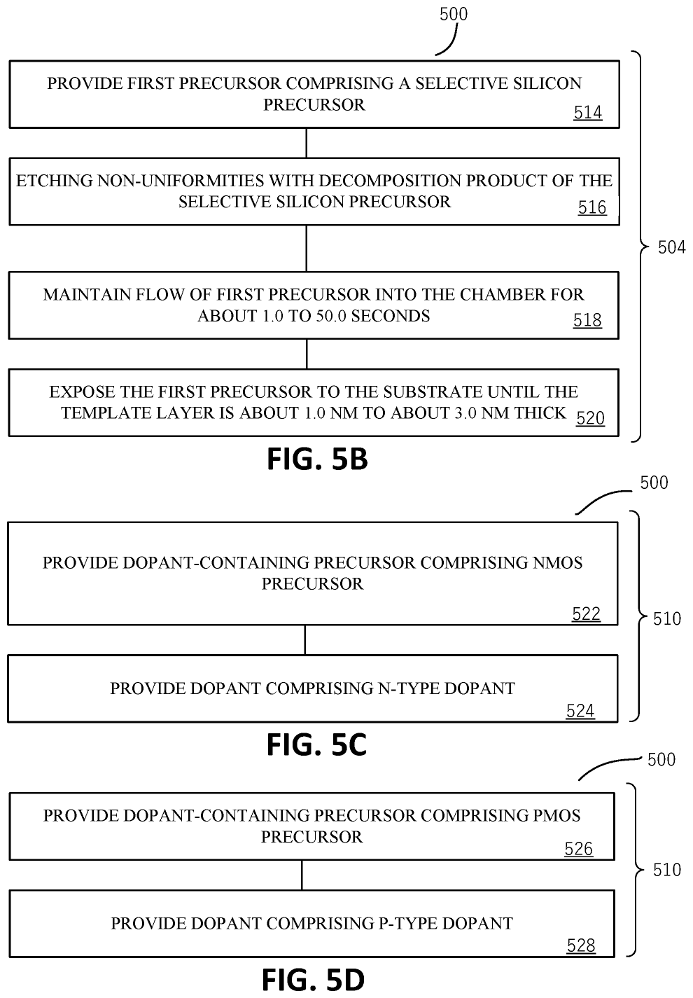

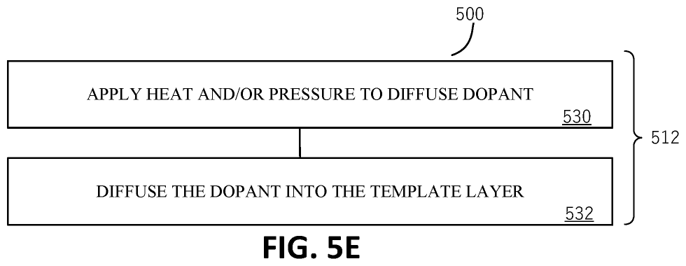

In an example, the precursor delivery arrangement 102, chamber arrangement and/or the exhaust arrangement 106, may be coupled to a system operation and control mechanism, controller 226. Controller 226 may provide electronic circuitry and mechanical components to selectively operate valves, manifolds, pumps and other equipment included in semiconductor processing system 100. Such circuitry and components operate to introduce precursors 204, 210 and 212 and/or purge/carrier gas 216 from the respective precursor sources 202, 206, 208 and purge/carrier gas source 214. The controller 226 also controls timing of gas pulse sequences, temperature of the substrate and chamber, and pressure of the chamber and various other operations necessary to provide proper operation of the semiconductor processing system 100. Controller 226 can include control software and electrically or pneumatically controlled valves to control flow of precursors, reactants and purge gasses into and out of the chamber arrangement 104. Controller 226 includes a device interface 240, a processor 244, a user interface 242, and a memory 246. The device interface 240 connects the processor 244 to the wired or wireless link 228. The processor 244 is operably connected to the user interface 242 (e.g., to receive user input and/or provide user output therethrough) and is disposed in communication with the memory 246. The memory 246 includes a computer program product comprising a non-transitory machine-readable medium having one or more program modules 248 recorded thereon containing instructions that, when read by the processor 244, cause the processor 244 responsive to instructions to execute certain operations. Program modules 248 may comprise software, firmware and/or hardware components configured to performs certain tasks. Among the operations are operations of a structure forming method 500 (shown in FIGS. 5A-5E), as will be described. As will be appreciated by those of skill in the art in view of the present disclosure, the controller 226 may have a different arrangement in other examples and remain within the scope of the present disclosure.

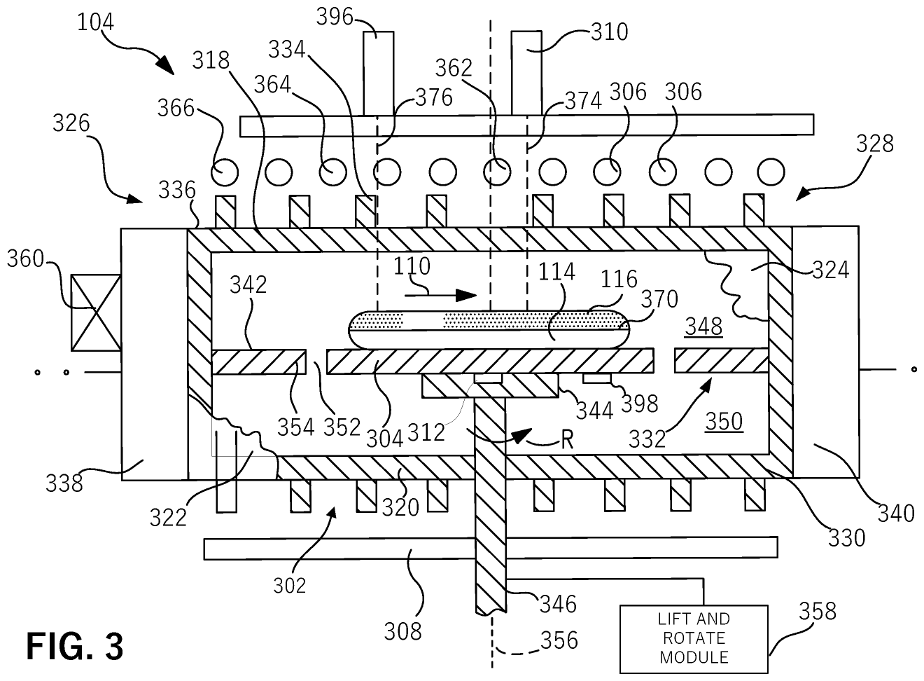

With reference to FIG. 3, the chamber arrangement 104 is shown. The chamber arrangement 104 includes a chamber body 302 and a substrate support 304. The chamber arrangement 104 also includes an upper heater element array 306 and a lower heater element array 308. The chamber arrangement 104 further includes pyrometers 310 and 396, thermocouples 312 and 398, a controller 226 (shown in FIG. 4), and a wired or wireless link 228 (shown in FIG. 4). Although a specific arrangement is shown and described herein it is to be understood and appreciated that the chamber arrangement 104 may include other elements and/or omit elements shown and described herein and remain within the scope of the present disclosure.

In an example, the chamber body 302 is configured to flow the precursor 110 across the substrate 114 and has an upper wall 318, a lower wall 320, a first sidewall 322, and a second sidewall 324. The upper wall 318 extends longitudinally between an injection end 326 and a longitudinally opposite exhaust end 328 of the chamber body 302, is supported horizontally relative to gravity, and is formed from a transmissive material 330. The lower wall 320 is below and parallel relative to the upper wall 318 of the chamber body 302, is spaced apart from the upper wall 318 by an interior 332 of the chamber body 302 and is also formed from the transmissive material 330. The first sidewall 322 longitudinally spans the injection end 326 and the exhaust end 328 of the chamber body 302, extends vertically between the upper wall 318 and the lower wall 320 of the chamber body 302, and is formed from the transmissive material 330. The second sidewall 324 is parallel to the first sidewall 322, is laterally opposite and spaced apart from the first sidewall 322 by the interior 332 of the chamber body 302 and is further formed from the transmissive material 330. In certain examples, the transmissive material 330 may include a ceramic material such as sapphire or quartz. In accordance with certain examples, the chamber body 302 may include a plurality of external ribs 334. The plurality of external ribs 334 may extend laterally about an exterior 336 of the chamber body 302 and be longitudinally spaced between the injection end 326 and the exhaust end 328 of the chamber body 302. In certain examples, one or more of the walls 318-324 may be substantially planar. In accordance with certain examples, one or more of the walls 318-324 may be arcuate or dome-like in shape. It is also contemplated that, in accordance with certain examples, the chamber body 302 may include no ribs.

In an example, an injection flange 338 and an exhaust flange 340 may be connected to the injection end 326 and the exhaust end 328, respectively, of the chamber body 302. The injection flange 338 may fluidly couple the precursor delivery arrangement 102 (shown in FIG. 1) to the interior 332 of the chamber body 302 and be configured to provide the precursor 110 to the interior 332 of the chamber body 302. The exhaust flange 340 may fluidly couple the interior 332 of the chamber body 302 to the exhaust arrangement 106. The exhaust flange 340 may be configured to communicate the residual precursor and/or reaction products 112 (shown in FIG. 1) issued by the chamber arrangement 104 during deposition of the template layer 116 and/or nucleation layer 410 (see FIG. 4) onto the substrate 114. In this respect the chamber body 302 may have a cold wall, cross-flow reactor configuration.

In an example, a divider 342, a support member 344, and a shaft member 346 may be arranged within the interior 332 of the chamber body 302. The divider 342 may be fixed within the interior 332 of the chamber body 302 and divide the interior 332 of the chamber body 302 into an upper chamber 348 and a lower chamber 350. The divider 342 may further define an aperture 352 therethrough, the aperture 352 fluidly coupling the upper chamber 348 of the chamber body 302 to the lower chamber 350 of the chamber body 302. The divider 342 may be formed from an opaque material 354. The opaque material 354 may include silicon carbide.

In an example, the substrate support 304 may be configured to seat thereon the substrate 114 and supported at least partially within the aperture 352 for rotation R about a rotation axis 356. The substrate support 304 may seat the substrate 114 such that a radially-outer peripheral portion of the substrate 114 abuts the substrate support 304 while a radially-inner central portion of the substrate 114 is spaced apart from the substrate support 304. The support member 344 may be arranged below the substrate support 304 and along the rotation axis 356. The support member 344 may be further arranged within the lower chamber 350 of the chamber body 302 and fixed in rotation relative to the substrate support 304 about the rotation axis 356 for rotation with the substrate support 304. The substrate support 304 may be formed from an opaque material, such as the opaque material 354 or a graphite material. The support member 344 may be formed from a transmissive material, such as the transmissive material 330.

In an example, the shaft member 346 may be arranged along the rotation axis 356 and fixed in rotation relative to the support member 344 about the rotation axis 356. The shaft member 346 may also extend through the lower chamber 350 of the chamber body 302 and through lower wall 320 of chamber body 302. The shaft member 346 may further operably connect a lift and rotate module 358 to the substrate support 304, the lift and rotate module 358 in turn may be configured to rotate R the substrate support 304 and the substrate 114 about the rotation axis 356 during deposition of the template layer 116 onto an upper surface 370 of the substrate 114. The lift and rotate module 358 may further cooperate with a gate valve 360 and a lift pin arrangement to seat and unseat the substrate 114 from the substrate support 304, such as through a substrate handling robot arranged within a cluster-type platform in selective communication with the interior 332 of the chamber body 302 through the gate valve 360. In certain examples the shaft member 346 may be formed from a transmissive material, such as the transmissive material 330.

As noted previously, in conventional epitaxial substrate processing, epitaxial growth starts with a nucleation layer deposited onto a substrate surface that serves as a seed for the crystal growth.

Important features of a high-quality nucleation layer are good crystal quality and minimal defects. Defect reduction is even more important in growth of doped silicon for source/drain applications on the beyond 5.0 nm node because of the complex 3D substrate. One of the problems that can arise when a nucleation layer is grown directly on a substrate surface having non-uniformities such as residual oxides or other defects is that at the growth front there may be surface segregation of dopant atoms at the defect sites. Such surplus dopant atoms can cause the growth surface to become uneven. The uneven surface can cause certain sites to grow faster than others leading to spurious growth and ultimately to device failure. Specifically, dopants will tend to aggregate preferentially at the defective regions on a growth surface which heightens any disparity in growth region site to site.

Because surface preparation methods can leave behind artifacts such as residual oxides, notches, raised areas and other non-uniformities a template upon which to grow the nucleation layer can provide a smoother substrate surface with fewer defects and non-uniformities compared to conventional surface treatments.

Referring now to FIG. 4 illustrating an example method 400 of depositing a material onto a substrate 114 to form a template layer 116 upon which to grow nucleation layer 410. In contrast to the conventional methods described above, method 400 disclosed herein includes first depositing a slow growing template layer 116 concurrently with an etchant to reduce incidence of non-uniformities on a surface of a substrate 114 and to prime growth of a nucleation layer 410 in epitaxial substrate processing. Controller 226 (see FIG. 2) may control method 400 implemented by the semiconductor processing system 100 by controlling operations of, for example, chamber arrangement 104 and/or precursor delivery arrangement 102.

In an example, substrate 114 may be provided in chamber body 302 (see FIG. 3) of a semiconductor processing system 100 (see FIG. 1). Method 400 may be initiated at operation 430 by controller 226 triggering a first precursor 212 to flow into chamber body 302 and to contact first surface 402 of substrate 114. First precursor 212 may comprise a selective precursor including a silicon source. A byproduct of decomposition of the selective precursor may be an etchant. During operation 430, the etchant may reduce non-uniformities 422 by etching high-energy areas of surface 402.

In an example, first precursor 212 may comprise selective silicon precursor dichlorosilane (H₂SiCl₂). As first precursor 212 is processing in chamber body 302, decomposition byproducts of dichlorosilane including hydrogen chloride (HCl), may form. When HCl contacts first surface 402 it may etch non-uniformities such as areas of higher energy that may comprise, as non-limiting examples, surface distortions, reactive areas, areas having highest probability of desorption, roughened areas, misaligned crystallographic orientation, raised or notched areas or and/or crystallographic imperfections, or the like. Etching of surface 402 may be performed by the etchant (e.g., HCl byproduct) and may occur simultaneously with growth of template layer 116. Thus, growth of silicon at surface 402 for template layer 116 is across a surface having non-uniformities reduced by HCl etching. Exposing surface 402 to dichlorosilane and its byproduct HCl provides a slow growing silicon template layer 116 having reduced surface defects from which a lowered defect crystal epitaxy may grow.

In some examples, selective precursors may preferentially deposit on selected surfaces or regions of substrate 114. This allows for the selective growth of film on specific areas of the substrate 114. For example, where a surface includes silicon and dielectric material, a selective precursor may preferentially grow an epitaxial layer off of the silicon and not the dielectric. In addition to the example selective precursor dichlorosilane, there are other selective precursors, such as but not limited to, trichlorosilane (SiHCl₃), monochlorosilane (SiHCl), and silane (SiH₄).

Optionally, method 400 may be initiated by controller 226 triggering operation 432, where first precursor 212 may comprise a different, non-chlorinated silicon source such as, silane. An etchant 420 (e.g., HCl) may be co-flowed with silane to etch non-uniformities 422 on surface 402 and grow a template layer 116.

Flowing the first precursor 212 may further comprise exposing substrate surface 402 to the first precursor 212 for a predetermined period of time. Such a period may last, in a non-limiting example, from about 0.5 seconds to about 100.0 seconds, or from about 1.0 second to about 80.0 seconds, or from about 1.0 second to about 50.0 seconds, or from about 1.0 second to about 20.0 seconds. Surface 402 may be exposed to first precursor 212 for one or more periods.

At operation 434, first precursor 212 may form a template layer 116 on surface 402 of substrate 114 to a desired thickness 416. Such a template layer 116 may prime growth of a subsequent nucleation layer 410. In an example, the desired thickness of template layer 116 is about 0.5 nm to about 20.0 nm thick or about 1.0 to about 15 nm thick or about 1.0 to about 5.0 nm thick or about 1.0 nm to about 3.0 nm thick.

In an example, once template layer 116 has grown to a desired thickness 416, at operation 436, a dopant-containing precursor 204 may be co-introduced with a first precursor 212 to begin growing the nucleation layer 410 on a top surface 404 of template layer 116. In some examples, at operation 438, dopant-containing precursor 204 may optionally be introduced along with second precursor 210 and/or etchant 420. In an example, first precursor 212 and second precursor 210 may be the same precursor. In another example, first precursor 212 and second precursor 210 may be different precursors.

At operation 440, nucleation layer 410 may take the shape of the underlying template layer 116. As the nucleation layer 410 film grows, the growth surface 412 may separate from the starting growth interface 414.

Dopant-containing precursor 204 may add dopant 424 to the nucleation layer 410 to alter its electrical properties. In one example, dopant-containing precursor 204 may be tailored to make an n-type metal-oxide-semiconductor (nMOS) nucleation layer for nMOS material that may be later grown. Examples of nMOS type dopants include phosphorus (P) and arsenic (As) or the like or combinations thereof. Examples of a dopant-containing precursor 204 for use in doping nucleation layer 410 with n-type dopants may be phosphine (PH₃), arsine (AsH₃) and/or tert-butylarsine (C₄H₉As), or the like. During method 400 tailored to producing an nMOS substrate, chamber body 302 may be heated to a temperature of between about 100° C. to about 800° C., or between about 150° C. to about 800° C., or between about 200° C. to about 800° C., for example 600° C. Pressure within chamber body 302 may be between about 1.0 Torr to about 800.0 Torr or between about 5.0 Torr to about 750.0 Torr, for example 600 Torr. Heating and pressurization of chamber body 302 may be controlled by controller 226.

In another example, dopant-containing precursor 204 may be tailored to make a p-type metal-oxide-semiconductor (pMOS) nucleation layer for pMOS material that may be later grown. Examples of pMOS type dopants include but are not limited to boron (B), aluminum (Al), and/or gallium (Ga) or the like or combinations thereof. Examples of dopant-containing precursor 204 for use in doping nucleation layer 410 with p-type dopants may be diborane (B₂H₆) and trimethylboron (B(CH₃)₃), or the like. During method 400 tailored to producing an pMOS substrate, chamber body 302 may be heated to a temperature of between about 40° C. to about 800° C., or between about 50° C. to about 400° C., or between about 70° C. to about 350° C., for example 300° C. Pressure within chamber body 302 may be between about 1.0 Torr to about 800.0 Torr or between about 5.0 Torr to about 750.0 Torr, for example 600 Torr. Heating and pressurization of chamber body 302 may be controlled by controller 226.

At operation 440, nucleation layer 410 may reach a desired thickness 406. At operation 442, dopant 424 may diffuse from one layer to another during method 400. Under processing conditions (e.g., high temperatures), dopant 424 may gain sufficient kinetic energy to move from nucleation layer 410 to template layer 116. Dopant 424 diffusion may also be driven by the concentration gradient 418 of dopant 424, which may cause dopant 424 to move from a high concentration area in nucleation layer 410 to a low concentration area in template layer 116. Thus, over the course of the deposition, dopant 424 atoms may diffuse into template layer 116. The rate of diffusion can be controlled by the temperature, the type of dopant 424, and the material being used. Processing conditions may be selected to control the diffusion of dopant 424 in order to impart desired electrical properties to substrate 114.

As will be appreciated by those of skill in the art in view of the present disclosure, controller 226 (see FIG. 2) can monitor and control various processes and equipment comprising semiconductor processing system 100 (see FIG. 1) in the production of semiconductor materials. Controller 226 (see FIG. 2) receives input from sensors and other devices that measure various parameters, such as temperature, pressure, and flow rate, and uses this information to adjust the operation of the equipment and processes as needed. Controller 226 may control temperature and pressure settings and the flow of gases or liquids through the semiconductor processing system 100 (see FIG. 1) which is important to controlling the growth of epitaxial layers by regulating the parameters that affect its growth. Controller 226 (see FIG. 2) may be programmed to perform other tasks, specific functions and capabilities of a controller in a substrate processing system will depend on the specific requirements of the application.

The following examples refer to FIGS. 5A-5E depicting flow charts illustrating a method 500 describing a process of depositing a material onto a substrate 114 to form a template layer 116 (see FIG. 4) upon which a nucleation layer 410 may be subsequently deposited. In an example, method 500 may proceed in a chamber arrangement, for example chamber arrangement 104 (see FIG. 1). FIGS. 5A-5E illustrate various operations of a material deposition method 500 that may in some examples be executed by controller 226. More specifically, operations of method 500 may be controlled and/or executed by controller 226 to selectively operate valves (e.g., gate valve 360 illustrated in FIG. 3), flanges (e.g., flanges 338 and 340), manifolds, pumps, substrate support 304, lift and rotate module 358, heating elements (e.g., heater element arrays 306 and 308), temperature sensors (e.g., pyrometers 310 and 396 and thermocouples 312 and 398), silicon-controlled rectifier (SCR) devices and other equipment included in semiconductor processing system 100 (see FIG. 1).

FIG. 5A is a flow chart illustrating an example material deposition method 500. In an example, method 500 may begin at block 502 where a substrate 114 (see FIG. 4) may be supported within chamber body 302 (see FIG. 3) of a semiconductor processing system 100 (see FIG. 1).

Method 500 may proceed to block 504, where a first precursor 212 (see FIG. 2) may be flowed into the chamber body 302 (see FIG. 3) to contact first surface 402 (see FIG. 4) of substrate 114 (see FIG. 4).

Method 500 may proceed to block 506 where a template layer 116 (see FIG. 4) of silicon film may be formed on the first surface 402 (see FIG. 4) of substrate 114. At block 508, non-uniformities 422 (see FIG. 4) may be etched from the first surface 402 of substrate 114. Method 500 may proceed to block 510 where a dopant-containing precursor 204 may be flowed into chamber body 302 (see FIG. 3) to contact a second surface of the substrate 114 (see FIG. 4) wherein the second surface is a top surface 404 of the template layer 116. In an example, dopant-containing precursor 204 may be co-flowed with first precursor 212 or with second precursor 210, or combinations thereof. In an example, first precursor 212 and second precursor 210 may be the same precursor. In another example, first precursor 212 and second precursor 210 may be different precursors. At block 512, a nucleation layer 410 may be formed on the second surface (i.e., top surface 404 illustrated in FIG. 4).

Referring now to FIG. 5B where example operations for block 504 of method 500 (see FIG. 5A) are further illustrated in a flow chart. At block 514, wherein the first precursor 212 is provided comprising a selective silicon precursor. At block 516, non-uniformities may be etched with a decomposition product of the selective precursor. At block 518, the first precursor 212 may be flowed to expose substrate 114 to first precursor 212 for about 1 to about 50 seconds. At block 520, the substrate 114 may be exposed to the first precursor 212 until the template layer 116 is about 1.0 nm to about 3.0 nm thick.

FIG. 5C is a flowchart showing further example operations for block 510 of method 500 (see FIG. 5A). At block 522, the second precursor 210 may be provided comprising an nMOS precursor such as, for example phosphine (PH₃), arsine (AsH₃) or tert-butylarsine (C₄H₉As) or a combination thereof. At block 524, the dopant-containing precursor 204 may be provided comprising an n-type dopant such as, for example, phosphorus (P) or arsenic (As), or a combination thereof.

FIG. 5D is a flowchart showing further example operations for block 510 of method 500 (see FIG. 5A). At block 526, the second precursor 210 may be provided comprising a pMOS precursor such as, for example, diborane (B₂H₆). At block 528, the dopant 204 may be provided comprising an p-type dopant such as, for example boron (B).

FIG. 5E is a flowchart showing further example operations for block 512 of method 500 (see FIG. 5A). At block 530, heat and/or pressure may be applied to diffuse dopant 204. At block 532, the dopant 204 may diffuse into template layer 116 from the nucleation layer 410 to a desired concentration.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of depositing a material onto a substrate, the method comprising:
supporting the substrate within a chamber of a semiconductor processing system;
flowing a first precursor into the chamber to contact a first surface of the substrate;
forming a template layer of silicon-containing film on the first surface of the substrate;
etching non-uniformities on the first surface of the substrate;
flowing a dopant-containing precursor into the chamber to contact a second surface of the substrate wherein the second surface is a top surface of the template layer; and
forming a nucleation layer on the second surface.

2. The method of claim 1, wherein the first precursor is a selective silicon precursor and wherein the etching is performed by a decomposition byproduct of the selective silicon precursor.

3. The method of claim 2, wherein the selective silicon precursor is dichlorosilane.

4. The method of claim 1, wherein flowing the first precursor further comprises exposing the first precursor to the substrate for about 1 to about 50 seconds.

5. The method of claim 1, wherein flowing the first precursor further comprises exposing the first precursor to the substrate until the template layer is about 1.0 nm to about 3.0 nm thick.

6. The method of claim 1, wherein the dopant-containing precursor is an n-type metal-oxide-semiconductor (nMOS) precursor comprising phosphine (PH3), arsine (AsH3) or tert-butylarsine (C4H9As), or a combination thereof.

7. The method of claim 6, wherein the dopant-containing precursor is co-flowed with a second precursor that is different from the first precursor.

8. The method of forming a structure of claim 1, wherein the dopant-containing precursor is a p-type metal-oxide-semiconductor (pMOS) precursor comprising diborane (B₂H₆) and wherein the dopant-containing precursor is co-flowed with a second precursor.

9. The method of claim 1, wherein forming the nucleation layer on the second surface further comprises applying heat or pressure or a combination thereof to diffuse a dopant into the template layer.

10. The method of claim 1, wherein a temperature within the chamber is about 100° to about 800° C. and wherein a pressure within the chamber is about 5 Torr to about 600 Torr.

11. A semiconductor processing system, comprising:
a chamber configured to support a substrate;
a first precursor source, a second precursor source and a dopant source connected to the chamber; and
a controller operably connected the first precursor source, the second precursor source and the dopant source, wherein the controller responsive to instructions recorded on a memory to:
support a substrate within a chamber of a semiconductor processing system;
flow a first precursor into the chamber to contact with a first surface of the substrate;
form a template layer of silicon-containing film on the first surface of the substrate;
etch non-uniformities on the first surface of the substrate simultaneously with forming the template layer;
flow a dopant-containing precursor into the chamber in contact with a second surface of the substrate wherein the second surface is a top surface of the template layer; and
form a nucleation layer on the second surface.

12. The semiconductor processing system of claim 11, wherein the first precursor is a selective silicon precursor, wherein a decomposition byproduct of the selective silicon precursor is an etchant.

13. The semiconductor processing system of claim 12, wherein the selective silicon precursor is dichlorosilane.

14. The semiconductor processing system of claim 11, wherein flowing the first precursor further comprises exposing the first precursor to the substrate for about 1 to about 50 seconds.

15. The semiconductor processing system of claim 11, wherein flowing the first precursor further comprises exposing the first precursor to the substrate until the template layer is between about 1 nm to about 3 nm thick.

16. The semiconductor processing system of claim 11, wherein the dopant-containing precursor is an nMOS precursor comprising phosphine (PH₃), arsine (AsH₃) or tert-butylarsine (C₄H₉As), or a combination thereof.

17. The semiconductor processing system of claim 11, wherein the dopant-containing precursor is a pMOS precursor comprising diborane (B₂H₆).

18. The semiconductor processing system of claim 11, further comprising diffusing a dopant into the template layer.

19. The semiconductor processing system of claim 11, wherein a temperature is about 100° C. to about 800° C. and wherein a pressure is about 5 Torr to about 600 Torr.

20. The semiconductor processing system of claim 11, wherein the dopant-containing precursor is co-flowed with a second precursor that is different from the first precursor.

21. A computer program product, comprising: a non-transitory machine-readable medium having one or more program modules recorded thereon containing instructions that, when read by a processor, causes the processor, responsive to instructions, to execute the method of claim 1.
